(19) United States
(12) Patent Application Publication
(10) Pub. No.: US 2016/0146436 A1
(43) Pub. Date: May 26, 2016

(54) LED UNIT AND LED MODULE HAVING THE SAME

(71) Applicant: Changshu Sunrex Technology Co., Ltd., Changshu (CN)

(72) Inventor: Qing ZHANG, Changshu (CN)

(21) Appl. No.: 14/552,843

(22) Filed: Nov. 25, 2014

(51) Int. Cl. F21V 19/00; F21V 23/06; H01L 33/48; F21V 17/10; H01L 33/52; H01L 33/62

(52) U.S. Cl. CPC F21V 19/0025; H01L 33/52; H01L 33/62; H01L 33/486; F21V 17/101; F21V 23/06; F21Y 2101/02

(57) ABSTRACT

An LED module includes a flexible printed circuit board including two bonding pads, an LED unit and a glue layer including two first glue portions and two second glue portions. The LED unit includes an insulating casing having a bottom surface that has a periphery region, an LED chip, and two conducting elements. Each of the conducting elements has a main portion disposed adjacent to the periphery region and spaced apart from a periphery of the bottom surface. Each of the first glue portions electrically interconnects a respective one of the bonding pads and the main portion of a respective one of the connecting elements. The second glue portions are disposed on the peripheral region to interconnect the LED unit and the flexible printed circuit board.

### FIELD OF THE INVENTION

This invention relates to an LED module, more particularly to an LED module including an LED unit, a flexible printed circuit board and a glue layer.

### BACKGROUND OF THE INVENTION

One type of conventional printed circuit board is composed of a flexible polymer film and an etched copper foil. This type of conventional printed circuit board provides good adhesion with electronic components, but is relatively expensive. Another type of conventional printed circuit board is composed of a flexible polymer film and a metal coil (e.g., silver coil or copper coil) printed on the flexible polymer film. This type of conventional printed circuit board is relatively low in cost, but offers inferior adhesion with electronic components.

Referring to FIGS. 1 and 2, a conventional surface-mount device (SMD) 9 is mounted on a flexible printed circuit board 8. The flexible printed circuit board 8 includes a flexible substrate 81, a pair of conducting wirings 82 formed on the flexible substrate 81, and two bonding pads 821 respectively extending from the conducting wirings 82. The conventional surface-mount device 9 includes an insulating casing 91 and two conducting elements 92, each of which is electrically connected to a respective one of the bonding pads 821 via a soldering tin 7.

After repeated flexing of the flexible substrate 81, an interface between each of the banding pads 821 and the respective one of the conducting wirings 82 may break.

### SUMMARY OF THE INVENTION

Therefore, an object of the present invention is to provide an LED module and an LED unit that can alleviate at least one of the drawbacks associated with the abovementioned prior arts.

According to a first aspect of the present invention, there is provided an LED module that includes a flexible printed circuit board, an LED unit disposed on the flexible printed circuit board, and a glue layer. The flexible printed circuit board includes a flexible substrate and two bonding pads disposed on the flexible substrate. The LED unit includes an insulating casing having a bottom surface that has a periphery region, an LED chip encapsulated in the insulating casing, and two conducting elements. Each of the conducting elements has a main portion disposed adjacent to the periphery region on the bottom surface of the insulating casing, is electrically connected to the LED chip, and is spaced apart from a periphery of the bottom surface of the insulating casing by the periphery region. The glue layer includes two first glue portions and two second glue portions. Each of the first glue portions is disposed between and electrically interconnects a respective one of the bonding pads of the flexible printed board and the main portion of a respective one of the connecting elements of the LED unit. The second glue portions are disposed on the periphery region of the bottom surface of the insulating casing to interconnect the LED unit and the flexible printed circuit board.

According to a second aspect of the present invention, there is provided an LED unit for being disposed on a flexible printed circuit board. The LED unit includes an insulating casing, an LED chip encapsulated in the insulating casing and two conducting elements. The insulating casing has a bottom surface that has a periphery region. Each of the conducting elements has a main portion that is disposed adjacent to the periphery region on the bottom surface of the insulating casing. Each of the conducting elements is electrically connected to the LED chip, and is spaced apart from a periphery of the bottom surface of the insulating casing by the periphery region.

### BRIEF DESCRIPTION OF THE DRAWINGS

Other features and advantages of the present invention will become apparent in the following detailed description of the embodiments with reference to the accompanying drawings, of which:

FIG. 1 is a perspective view illustrating a conventional surface-mount device (SMD) mounted on a flexible printed circuit board;

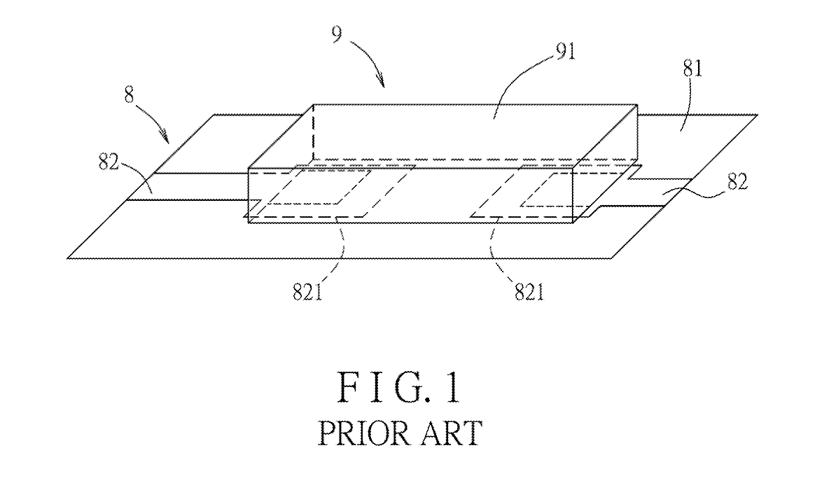

FIG. 2 is a sectional view showing the conventional surface-mount device and the flexible printed circuit board shown in FIG. 1;

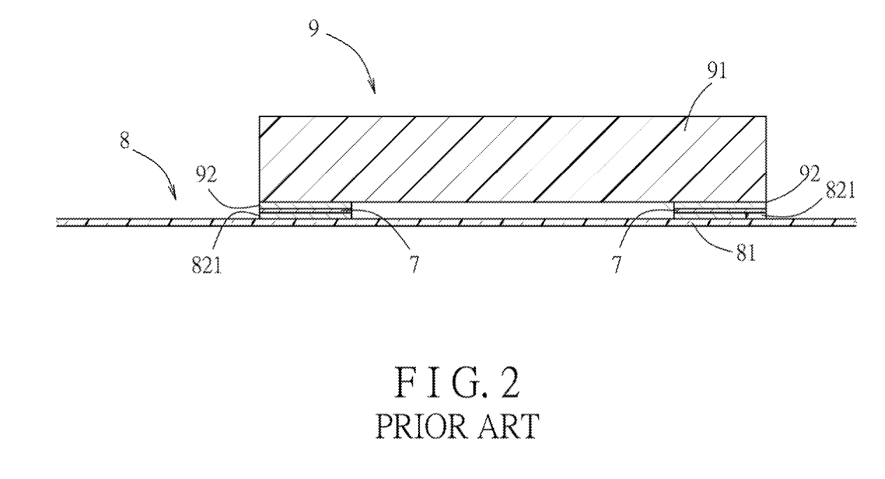

FIG. 3 is a perspective view of a first embodiment of an LED module of the present invention, which includes an LED unit disposed on a flexible printed circuit board;

FIG. 4 is a sectional view of the first embodiment;

FIG. 5 is a perspective view showing a second embodiment of an LED module of the present invention; and

FIG. 6 is a perspective view showing a third embodiment of an LED module of the present invention.

### DETAILED DESCRIPTION OF THE EXEMPLARY EMBODIMENTS

Before the present invention is described in greater detail with reference to the accompanying embodiments, it should be noted herein that like elements are denoted by the same reference numerals throughout the disclosure.

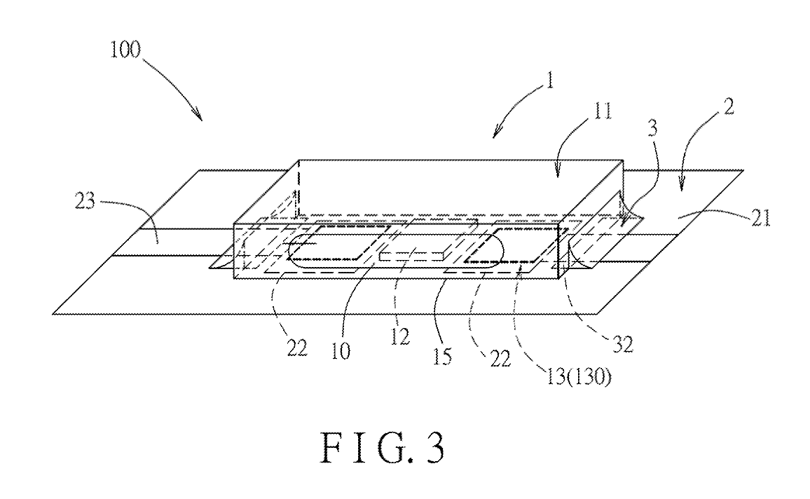

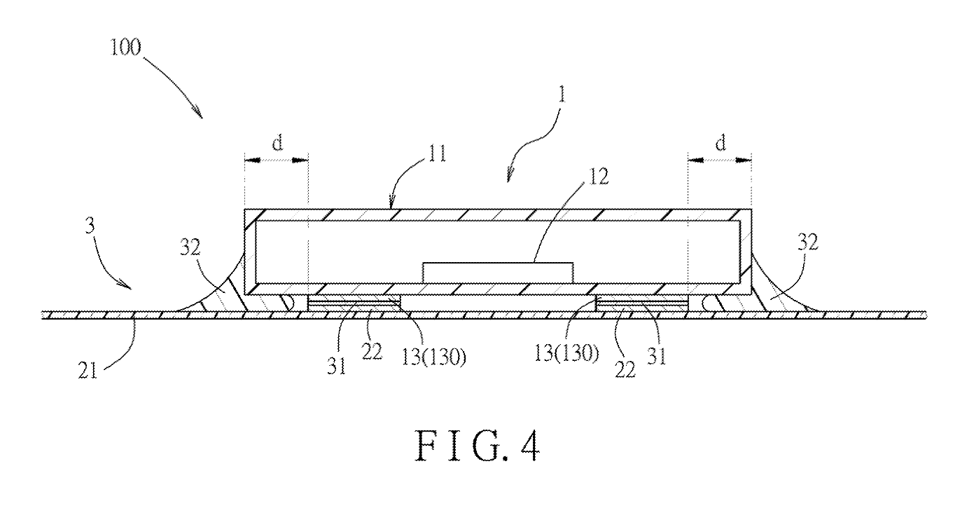

Referring to FIGS. 3 and 4, a first embodiment of an LED module 100 of the present invention includes an LED unit 1, a flexible printed circuit board 2 and a glue layer 3.

The flexible printed circuit board 2 includes a flexible substrate 21, two bonding pads 22 separately disposed on the flexible substrate 21, and a pair of conducting wirings 23. Each of the conducting wirings 23 extends from and is electrically connected to a corresponding one of the bonding pads 22. The flexible substrate 21 may be made from polyethylene terephthalate (PET). The bonding pads 22 may be made from silver. Alternatively, the flexible substrate 21 may be made from polyimide (PI), and bonding pads 22 may be made from copper or other conductive materials.

The LED unit 1 is disposed on the flexible printed circuit board 2 and includes an insulating casing 11 having a bottom surface that has a periphery region, an LED chip 12 encapsulated in the insulating casing 11, and two spaced apart conducting elements 13 formed on the bottom surface of the insulating casing 11 and exposing the periphery region.

The bottom surface of the insulating casing 11 has a periphery 15. In the first embodiment, the periphery 15 has a rectangular shape and has two opposing long sides and two opposing short sides.

Each of the conducting elements 13 has a main portion 130 that is disposed adjacent to the periphery region on the bottom surface of the insulating casing 11, that is spaced apart from the periphery 15 by the periphery region, and that is electrically connected to the LED chip 12. The periphery region between the main portion 130 of each of the conducting elements 13 and the periphery 15 has a minimum width (d) not less than 0.5 mm. To be more specific, in this embodiment, the periphery region between the main portion 130 of each of the conducting elements 13 and a corresponding one of the short sides of the periphery 15 has a minimum width (d) not less than 0.5 mm (see FIG. 4).

The glue layer 3 includes two first glue portions 31 and two second glue portions 32. Each of the first glue portions 31 is disposed between and electrically interconnects a respective one of the bonding pads 22 of the flexible printed circuit board 2 and the main portion 130 of a respective one of the connecting elements 13 of the LED unit 1. The second glue portions 32 are disposed on the peripheral region of the bottom surface of the insulating casing 11 to interconnect the LED unit 1 and the flexible printed circuit board 2 for enhancing bonding strength therebetween. In this embodiment, each of the second glue portions 32 covers a corresponding one of the conducting wirings 23 located under the peripheral region and is spaced apart from a respective one of the first glue portions. It should be noted that the second glue portions 32 may extend to a lateral surface (perpendicularly extending from the periphery 15 of the bottom surface) of the insulating casing 11 for further enhancing bonding strength between the LED unit 1 and the flexible printed circuit board 2. The first glue portions 31 are conductive adhesives made from, e.g., tin or silver. The second glue portions 32 may be conductive or non-conductive adhesives.

The lateral surface of the insulating casing 11 includes a lateral lighting portion 10 that permits light emitted from the LED chip 12 to exit from the insulating casing 11 toward a light guide film (not shown). The light transmitted in the light guide film could emit toward a keyboard apparatus (not shown) so as to provide a lighting keyboard apparatus. It is worth mentioning that since the arrangement of the LED unit 1 with the lateral lighting portion 10, the light guide film and the keyboard apparatus is well known to a skilled artisan and can vary based on practical requirements, detailed descriptions thereof are omitted herein for the sake of brevity.

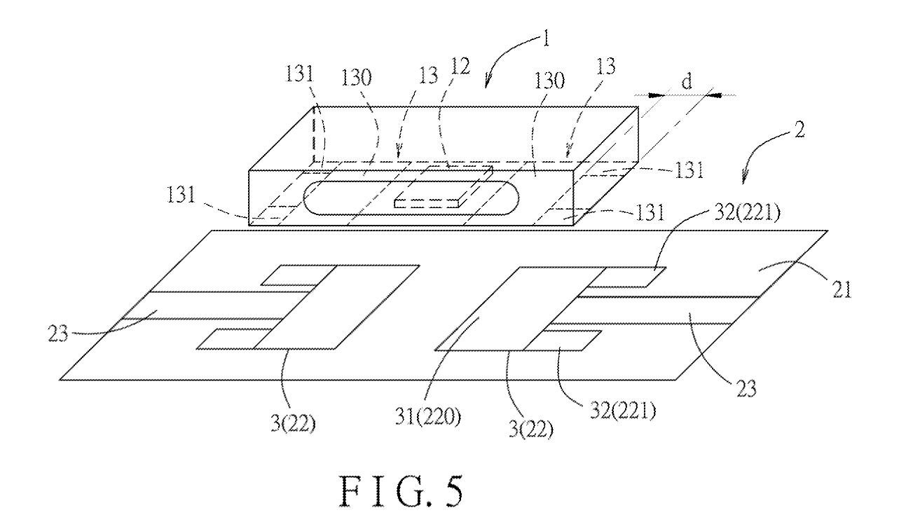

FIG. 5 shows a second embodiment of an LED module 100 of the present invention which has a structure similar to that of the first embodiment. The differences reside in the configurations of the conducting elements 13 of the LED unit 1, the bonding pads 22 of the flexible printed circuit board 2, and the second glue portions 32 of the glue layer 3. Each of the conducting elements 13 further has two spaced apart extending portions 131 connecting to an end of the main portion 130 and formed on the periphery region such that a part of the periphery region between the extending portions 131 of each of the conducting elements 13 is exposed. Each of the bonding pads 22 has a connecting portion 220 that overlaps the main portion 130 of a corresponding one of the conducting elements 13, and a pair of arm portions 211 that are connected to an end of the connecting portion 220, that are spaced apart from each other by a respective one of the conducting wirings 23, and that respectively overlap two extending portions 131 of the corresponding one of the conducting elements 13. Each of the first glue portions 31 is disposed on the connecting portion 220 of a corresponding one of the bonding pads 22 to connect the connecting portion 220 and the main portion 130. Each of the second glue portions 32 is disposed on the arm portions 221 of the corresponding one of the bonding pads 22 to connect the arm portions 221 and the extending portions 131.

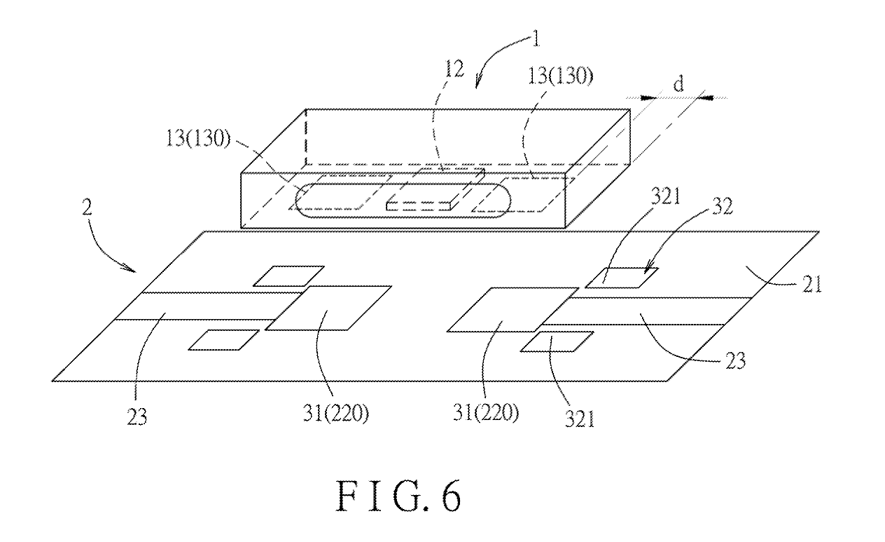

FIG. 6 shows a third embodiment of an LED module 100 of the present invention which has a structure similar to that of the first embodiment. The difference resides in the configuration of the second glue portions 32 of the glue layer 3. Each of the second glue portions 32 has two glue parts 321 that are disposed respectively at two opposite sides of a corresponding one of the conducting wirings 23 and that are spaced apart from the corresponding one of the conducting wirings 23. Likewise, the glue parts 321 of each of the second glue portions 32 may be conductive or nonconductive adhesives.

To sum up, by virtue of the second glue portions 32 that are respectively located between the periphery of the insulating casing 11 and the first glue portions 31, bonding strength between the LED unit 1 and the flexible printed circuit board 2 could be enhanced and the problem of breakage at an interface between the bonding pad and the conducting wiring likely to occur in the prior art could be alleviated.

While the present invention has been described in connection with what are considered the most practical embodiments, it is understood that this invention is not limited to the disclosed embodiments but is intended to cover various arrangements included within the spirit and scope of the broadest interpretation so as to encompass all such modifications and equivalent arrangements.

What is claimed is:

1. An LED module, comprising:
a flexible printed circuit board that includes a flexible substrate and two bonding pads disposed on said flexible substrate;
an LED unit that is disposed on said flexible printed circuit board, and that includes an insulating casing having a bottom surface that has a periphery region, an LED chip encapsulated in said insulating casing, and two conducting elements, each having a main portion being disposed adjacent to said periphery region on said bottom surface of said insulating casing, being electrically connected to said LED chip, and being spaced apart from a periphery of said bottom surface of said insulating casing by said periphery region; and
a glue layer that includes
two first glue portions, each being disposed between and electrically interconnecting a respective one of said bonding pads of said flexible printed circuit board and said main portion of a respective one of said connecting elements of said LED unit, and
two second glue portions disposed on said peripheral region of said bottom surface of said insulating casing to interconnect said LED unit and said flexible printed circuit board.

2. The LED module as claimed in claim 1, wherein each of said second glue portions is spaced apart from a respective one of said first glue portions.

3. The LED module as claimed in claim 1, wherein each of said conducting elements further has two spaced apart extending portions connecting to an end of said main portion and formed on said periphery region, each of said bonding pads having a connecting portion that overlaps said main portion of a corresponding one of said conducting elements, and a pair of spaced apart arm portions that are connected to an end of said connecting portion and that respectively overlap two extending portions of the corresponding one of said conducting elements, each of said first glue portions being disposed on said connecting portion of a corresponding one of said bonding pads, each of said second glue portions being disposed on said arm portions of the corresponding one of said bonding pads.

4. The LED module as claimed in claim 1, wherein said flexible printed circuit board further includes a pair of conducting wirings, each being electrically connected to a corresponding one of said bonding pads, each of said second glue portions having two glue parts that are disposed respectively at two opposite sides of a corresponding one of said conducting wirings and that are spaced apart from the corresponding one of said conducting wirings.

5. The LED module as claimed in claim 1, wherein said LED unit further includes a lateral lighting portion that permits light emitted from said LED chip to exit from said insulating casing.

6. The LED module as claimed in claim 1, wherein said periphery region has a minimum width not less than 0.5 mm.

7. An LED unit for being disposed on a flexible printed circuit board to make up an LED module, said LED unit comprising:
an insulating casing having a bottom surface that has a periphery region;
an LED chip encapsulated in said insulating casing; and
two conducting elements, each having a main portion being disposed adjacent to said periphery region on said bottom surface of said insulating casing, being electrically connected to said LED chip, and being spaced apart from a periphery of said bottom surface of said insulating casing by said periphery region.

8. The LED unit as claimed in claim 7, wherein each of said conducting elements further includes two spaced apart extending portions connecting to an end of said main portion and formed on said periphery region.

9. The LED unit as claimed in claim 7, wherein said periphery region has a minimum width not less than 0.5 mm.
